(19) United States
(12) Patent Application Publication
(10) Pub. No.: US 2022/0158401 A1
(43) Pub. Date: May 19, 2022

(54) PRESSURE-CONTROLLED SPECTRAL FEATURE ADJUSTER

(71) Applicant: Cymer, LLC, San Diego, CA (US)

(72) Inventors: Eric Anders Mason, San Diego, CA (US); Gamaralalage G. Padmabandu, San Diego, CA (US)

(21) Appl. No.: 17/440,230

(22) PCT Filed: Mar. 3, 2020
(86) PCT No.: PCT/US2020/020802

§ 371 Date: Sep. 17, 2021

Related U.S. Application Data
(60) Provisional application No. 62/824,525, filed on Mar. 27, 2019.

(51) Int. Cl. H01S 3/00; H01S 3/23; G03F 7/20

(52) U.S. Cl. CPC H01S 3/0078; H01S 3/2308; G03F 7/70191; G03F 7/70575; G03F 7/70883; G03F 7/70591; G03F 7/70158

(57) ABSTRACT

An apparatus includes a gas discharge system including a gas discharge chamber and configured to produce a light beam; and a spectral feature adjuster in optical communication with a pre-cursor light beam generated by the gas discharge chamber. The spectral feature adjuster includes: a body defining an interior that is held at a pressure below atmospheric pressure; at least one optical pathway defined between the gas discharge chamber and the interior of the body, the optical pathway being transparent to the pre-cursor light beam; and a set of optical elements within the interior, the optical elements configured to interact with the pre-cursor light beam.

### CROSS REFERENCE TO RELATED APPLICATION

This application claims priority to U.S. Application No. 62/824,525, filed Mar. 27, 2019 and titled PRESSURE-CONTROLLED SPECTRAL FEATURE ADJUSTER, and which is incorporated herein in its entirety by reference.

### TECHNICAL FIELD

The disclosed subject matter relates to a pressure-controlled spectral feature adjuster.

### BACKGROUND

In semiconductor lithography (or photolithography), the fabrication of an integrated circuit (IC) requires a variety of physical and chemical processes performed on a semiconductor (for example, silicon) substrate (which is also referred to as a wafer). A lithography exposure apparatus (which is also referred to as a scanner) is a machine that applies a desired pattern onto a target region of the substrate. The substrate is irradiated by a light beam that is produced from an optical source. The light beam has a wavelength in the ultraviolet range, somewhere between visible light and x-rays, and thus has a wavelength between about 10 nanometers (nm) to about 400 nm. The light beam can have a wavelength in the deep ultraviolet (DUV) range, for example, with a wavelength that can fall from about 100 nm to about 400 nm or a wavelength in the extreme ultraviolet (EUV) range, with a wavelength between about 10 nm and about 100 nm. These wavelength ranges are not exact, and there can be overlap between whether light is considered as being DUV or EUV. An accurate knowledge of spectral features or properties (for example, a bandwidth or a wavelength) of the light beam output from the optical source is important as well as the ability to control these spectral features or properties.

### SUMMARY

In some general aspects, a spectral feature adjuster includes: a body defining an interior that is held at a pressure below atmospheric pressure; at least one optical pathway through the body, the optical pathway being transparent to a light beam having a wavelength in the ultraviolet range; a set of optical elements within the interior, the optical elements in the set being configured to interact with the light beam, wherein the set of optical elements include one or more actuatable optical elements; and an actuation system within the interior, the actuation system being in communication with the one or more actuatable optical elements and configured to adjust a physical aspect of the one or more actuatable optical elements.

Implementations can include one or more of the following features. For example, the spectral feature adjuster can include a vacuum port defined in a wall of the body, the vacuum port being in fluid communication with the interior and with a vacuum pump external to the spectral feature adjuster. The spectral feature adjuster can include a pressure sensor configured to measure a pressure within the interior.

The set of optical elements can include a set of refractive elements; and a diffractive element. Each refractive element can be a prism and the diffractive element can be a grating. The set of refractive elements can include a set of four prisms.

The actuation system can include, for each actuatable optical element, an actuator configured to adjust a physical aspect of that actuatable optical element.

The spectral feature adjuster can also include an actuation interface defined in the body, the actuation interface in communication with the actuation system and to a control system external the spectral feature adjuster.

The interior can be held at a pressure at or below 16 kilopascals (kPa), at or below 12 kPa, or at or below 8 kPa. The interior can be held within 400 pascals (Pa) of an operating pressure or within 140 Pa of the operating pressure or within 20 Pa of the operating pressure.

The interior can lack helium. The interior can include a purge gas. The purge gas can include nitrogen.

The body can include a purge port fluidly communicating the interior with a source of the purge gas.

At least part of the body can be defined by a motion dampening device that physically couples to a gas discharge body of the gas discharge chamber, and the optical pathway can extend through an interior of the motion dampening device and through an optical port defined in the gas discharge body. The body can be hermetically-sealed and the interior of the motion dampening device can be held at the same pressure as the interior of the body.

In other general aspects, an apparatus includes: a gas discharge system including a gas discharge chamber and configured to produce a light beam; and a spectral feature adjuster in optical communication with a pre-cursor light beam generated by the gas discharge chamber. The spectral feature adjuster includes: a body defining an interior that is held at a pressure below atmospheric pressure; at least one optical pathway defined between the gas discharge chamber and the interior of the body, the optical pathway being transparent to the pre-cursor light beam; and a set of optical elements within the interior, the optical elements configured to interact with the pre-cursor light beam.

Implementations can include one or more of the following features. For example, the apparatus can include a control apparatus in communication with the gas discharge system and the spectral feature adjuster. The apparatus can include a pressure sensor configured to measure a pressure within the interior. The control apparatus can include a pressure module in communication with the pressure sensor and configured to receive the measured pressure and determine whether the measured pressure is within an acceptable range of pressures. The apparatus can also include a vacuum pump. The spectral feature adjuster can include a vacuum port defined in the body, the vacuum port being in fluid communication with the interior and with the vacuum pump. The pressure module can be in communication with the vacuum pump and can be configured to control operation of the vacuum pump based, at least in part, on the determination regarding the measured pressure.

The spectral feature adjuster can include an actuation system within the interior, the actuation system being in communication with one or more optical elements in the interior and configured to adjust a physical aspect of the one or more optical elements to thereby adjust one or more spectral features of the pre-cursor light beam. The control apparatus can include a spectral feature module in communication with the actuation system, the spectral feature module configured to receive estimates of one or more spectral features of the light beam and to adjust a signal to the actuation system based on the received estimates.

The apparatus can also include a source of purge gas in fluid communication with the interior. The control apparatus can include a purge gas module in communication with the purge gas source and configured to control a flow of purge gas from the purge gas source into the interior.

The gas discharge system can include: a first gas discharge stage including the gas discharge chamber that is configured to generate a seed light beam from the pre-cursor light beam; and a second gas discharge stage configured to receive the seed light beam and to amplify the seed light beam to thereby produce the light beam from the gas discharge system. The first gas discharge stage including the gas discharge chamber can house an energy source and can contain a gas mixture that includes a first gain medium; and the second gas discharge stage can include a gas discharge chamber housing an energy source and containing a gas mixture that includes a second gain medium.

The gas discharge chamber can house an energy source and contain a gas mixture that includes a first gain medium.

The interior can be held at a pressure at or below 16 kPa, at or below 12 kPa, or at or below 8 kPa.

The body can include a primary body housing the set of optical elements and a motion dampening device between the primary body and a gas discharge body of the gas discharge chamber, the interior of the motion dampening device providing at least part of the optical pathway between the gas discharge chamber and the interior. The apparatus can include an optical window between the motion dampening device and the gas discharge chamber, the optical window providing a hermetic separation between the interior of the body and the gas discharge chamber. The interior of the motion dampening device and the interior of the body can be fluidly open to each other such that the interior of the motion dampening device is at the same pressure as the interior of the body.

In other general aspects, a method of controlling a spectral feature of a light beam includes, while operating a gas discharge system in standby mode: injecting an interior of a body of a spectral feature adjuster with a purge gas; and pumping matter out of the interior of the spectral feature adjuster body until the pressure within the interior of the spectral feature adjuster body is below atmospheric pressure. The method includes determining whether the pressure within the interior of the spectral feature adjuster body is within an operating range of pressures; and, if it is determined that the pressure within the interior of the spectral feature adjuster body is within the operating range of pressures, then switching from operating the gas discharge system in the standby mode to operating the gas discharge system in output mode.

Implementations can include one or more of the following features. For example, the method can include, while operating the gas discharge system in output mode: determining whether the pressure within the interior of the spectral feature adjuster body is within an operating range of pressures; and, if it is determined that the pressure within the interior of the spectral feature adjuster body is outside the operating range of pressures, then adjusting pressure of the interior of the spectral feature adjuster body. If it is determined that the pressure within the interior of the spectral feature adjuster body is above the operating range of pressures, then the method can include adjusting pressure of the interior of the spectral feature adjuster body comprises pumping matter out of the interior of the spectral feature adjuster body. Adjusting pressure of the interior of the spectral feature adjuster body can include opening in a controlled manner the interior of the spectral feature adjuster body to atmosphere or stopping pumping matter out of the interior of the spectral feature adjuster body.

The operating range of pressures can be centered about an operating pressure that is at or below 16 kPa, at or below 12 kPa. or at or below 8 kPa. The operating range of pressures can be 400 Pa, 140 Pa, or 20 Pa.

The method can also include, prior to operating the gas discharge system in standby mode, hermetically sealing the interior of the spectral feature adjuster body from a gas discharge cavity of the gas discharge system, the gas discharge cavity being in optical communication with the interior of the spectral feature adjuster of the gas discharge system by way of an optical pathway. The gas discharge system can be operated in output mode by directing a pre-cursor light beam between the gas discharge cavity and the interior of the spectral feature adjuster body so that the pre-cursor light beam interacts with optical elements within the interior of the spectral feature adjuster body.

### DESCRIPTION OF DRAWINGS

FIG. 1 is a block diagram of a spectral feature adjuster including a body defining an interior having a controlled environment and housing optical elements that are configured to interact with a light beam;

FIG. 2 is a block diagram of an implementation of the spectral feature adjuster of FIG. 1 showing communications between the interior of the spectral feature adjuster and an exterior of the spectral feature adjuster;

FIG. 3 is a block diagram of an implementation of the spectral feature adjuster of FIG. 1, showing details of an actuation system coupled to the optical elements;

FIG. 4 is a block diagram of an implementation of the spectral feature adjuster of FIG. 1 configured to interact with a pre-cursor light beam from gas discharge system;

FIG. 5 is a block diagram of an implementation of the spectral feature adjuster of FIG. 4, showing details of an optical pathway between the gas discharge system and the spectral feature adjuster;

FIG. 6 is a block diagram of an implementation of the spectral feature adjuster of FIGS. 4 and 5, showing an implementation of the optical pathway between the gas discharge system and the spectral feature adjuster as well as an implementation of the gas discharge system;

FIG. 7 is a block diagram of an implementation of the spectral feature adjuster of FIGS. 4-6, showing a two-stage implementation of the gas discharge system;

FIG. 8 is a block diagram of an implementation of the spectral feature adjuster of FIGS. 4-6, showing a single stage implementation of the gas discharge system;

FIG. 9A is a top plan view of an implementation of the spectral feature adjuster of FIGS. 1-6;

FIG. 9B is a schematic illustration showing how the light beam interacts with an optical element that is a prism in the spectral feature adjuster of FIG. 9A;

FIGS. 10A and 10B are top and bottom perspective views of the body of the spectral feature adjuster of FIG. 9A;

FIG. 11 is a graph of an illustration of an optical spectrum of the light beam that interacts with the spectral feature adjuster of FIGS. 1-8; and

FIG. 12 is a flow chart of an implementation of a procedure for controlling a pressure within the spectral feature adjuster of FIGS. 1-8.

### DESCRIPTION

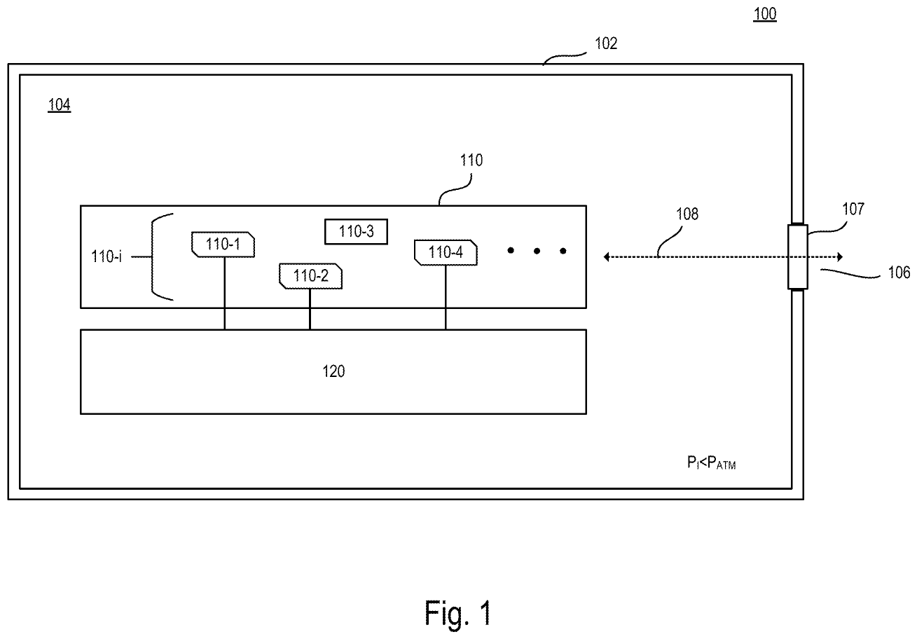

Referring to FIG. 1, a spectral feature adjuster 100 includes a body 102 defining an interior 104. The spectral feature adjuster 100 includes at least one optical pathway 106 defined in the body 102, the optical pathway 106 configured to be transparent to a light beam 108 having a wavelength in the ultraviolet range. Thus, the optical pathway 106 is transparent to a light beam 108 having a wavelength between about 10 nanometers (nm) to about 400 nm. In some implementations in which the spectral feature adjuster 100 is incorporated into a deep ultraviolet (DUV) light source, the optical pathway 106 is transparent to a light beam 108 having a wavelength in the DUV range, for example, from about 100 nm to about 400 nm. The light beam 108 can be a light beam that emits light not in a continuous mode, but rather in the form of optical pulses.

The spectral feature adjuster 100 includes a set 110 of optical elements 110-i, where i is a positive integer. In this example, four optical elements 110-1, 110-2, 110-3, 110-4 are shown (i=4), but the set 110 can include fewer than four or more than four optical elements 110-i. Each optical element 110-i in the set 110 is configured to optically interact with the light beam 108. This means that the light beam 108 is optically modified by the interaction with each optical element 110-i. Thus, for example, the light beam 108 can be refracted, reflected, deflected, diffracted, transmitted, expanded or contracted, or magnified due to its interaction with one or more of the optical elements 110-i. Each optical element 110-i in the set can be distinct from the other optical elements 110-i in the set. As an example, one or more of the optical elements 110-i can be refractive optical elements such as prisms. As another example, one or more of the optical elements 110-i can be a reflective optical element such as a mirror or beam splitter. At least one of the optical elements 110-i can be a diffractive optical element such as a grating. In operation, the light beam 108 is directed to the spectral feature adjuster 100 and adjustments are made to the light beam 108 based on how the light beam 108 optically interacts with the optical elements 110-i. In this way, one or more spectral features (such as bandwidth or wavelength) of the light beam 108 can be adjusted.

At least some of the optical elements 110-i are actuatable. For example, in the implementation shown in FIG. 1, optical elements 110-1, 110-2, 110-4 are actuatable. The actuatable optical elements 110-1, 110-2, 110-4 are physically adjustable in some manner so that their interaction with the light beam 108 can be modified. The adjustment to the actuatable optical element 110-1, 110-2, or 110-4 can occur either while the light beam 108 is interacting with the actuatable optical element 110-1, 110-2, or 110-4 or while there is no interaction between the light beam 108 and the actuatable optical element 110-1, 110-2, or 110-4. The actuatable optical elements 110-1, 110-2, 110-4 are physically adjustable in that one or more physical aspects of each actuatable optical element 110-1, 110-2, 110-4 is adjustable. For example, physical aspects of each of the actuatable optical elements 110-1, 110-2, 110-4 can be physically adjusted by being rotated, translated, vibrated, twisted, and/or warped. For example, the actuatable optical element 110-1 can be configured to be rotated while the actuatable optical element 110-2 can be configured to be translated. In other examples, a property such as the refractive index, of the actuatable optical element 110-4 can be configured to be modulated. Moreover, different actuatable optical elements 110-1, 110-2, 110-4 can be physically adjusted in different ways.

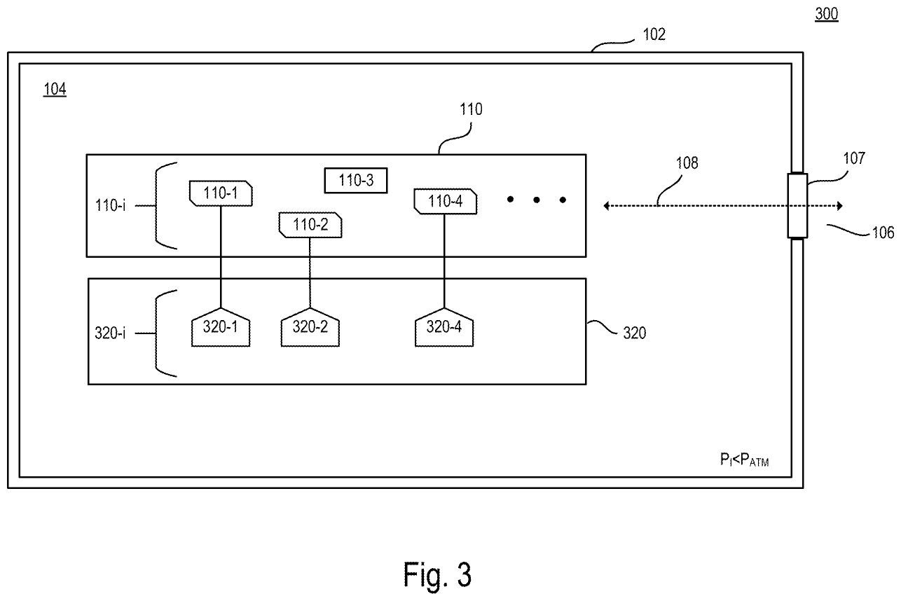

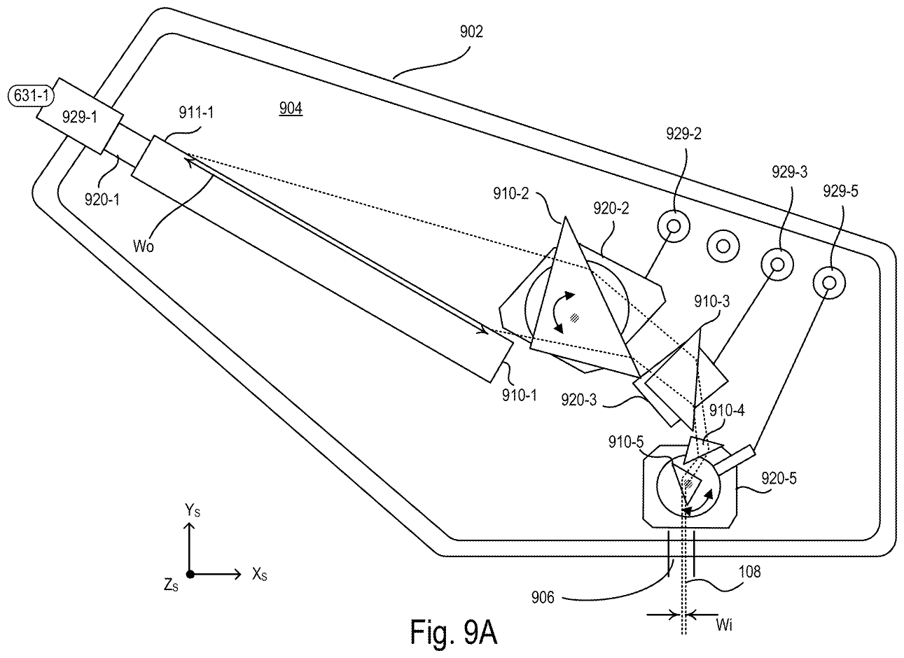

The spectral feature adjuster 100 also includes an actuation system 120 housed within the interior 104. The actuation system 120 is in communication with the one or more actuatable optical elements 110-1, 110-2, 110-4. In this way, the actuation system 120 is configured to affect the adjustment of the physical aspect of the actuatable optical elements 110-1, 110-2, 110-4. Implementations of the set 110 of optical elements 110-i and the actuation system 120 are provided with reference to FIGS. 3 and 9A.

The environment within the interior 104 of the body 102 can be controlled to reduce damage that can happen to components exposed to the interior 104 such as the optical elements 110-i in the set 110 and to the actuation system 120. Certain chemical substances, elements, or mixtures can damage the optical elements 110-i or adversely affect how the light beam 108 interacts with the optical elements 100-i. As an example, oxygen can attenuate the light beam 108 while the light beam 108 is interacting with the optical elements 110-i in the set 110. Oxygen can create other unwanted chemical substances such as ozone when interacting with the light beam 108, and such unwanted chemical substances can damage the optical elements 110-i and/or the actuation system 120. Other chemical substances, elements, or mixtures can further heat up during operation of the spectral feature adjuster 100 (that is, while the light beam 108 interacts with the optical elements 110-i). When heated, some chemical substances, elements, or mixtures can produce large changes in the index of refraction of the pathway traversed by the light beam 108 within the interior 104, and this can create undesirable thermal lensing. Ultimately, these problems lead to a degradation in operation of the spectral feature adjuster 100. In particular, these problems lead to a degradation in how accurately the spectral feature adjuster 100 controls or adjusts the spectral feature or features of the light beam 108 and can also lead into a degradation of other performance parameters such as energy or power of the light beam 108.

Because of this, unwanted chemical substances, elements, or mixtures are removed from the interior 104 either during operation of the spectral feature adjuster 100 (that is, while the light beam 108 is interacting with one or more of the optical elements 110-i) or at other times. For example, oxygen can be purged from the interior 104 using another chemical (in the form of a gas) such as nitrogen or helium. However, the use of a purge gas can cause pressure and refractive index transients within the interior 104 due to the flow of the purge gas across the path of the light beam 108. Such transients can lead to transients in the spectral features or performance parameters of the light beam 108. In order to reduce these transients and also reduce the amount of or need for purge gas, the interior 104 is held at a pressure P_{I} below atmospheric pressure P_{ATM}. Indeed, by maintaining a vacuum environment within the interior 104, it is possible to eliminate the need for using helium as a purge gas.

It is also possible to reduce a density of any purge gas (such as nitrogen) that is used in the body 102 by maintaining the interior 104 at sub-atmospheric pressure P_{I}. Additionally, the index of refraction of the purge gas in the interior 104 is a function of a density, a pressure, and a temperature of the purge gas. Reducing the density and the pressure of the purge gas in the interior 104 significantly reduces undesired thermal lensing effects due to changes in the index of refraction that occur with changes in temperature of the purge gas. The reduction of the density of the purge gas in the interior 104 also reduces a convective heat transfer rate from optical components to the purge gas, which can reduce a rate of temperature increase of the purge gas.

The pressure P_{I} of the interior 104 is controlled (for example, with a control apparatus, as discussed below) so that the pressure P_{I} is maintained to within an acceptable range of pressures and also to reduce fluctuations in the pressure P_{I} during operation of the spectral feature adjuster 100.

In order to maintain a vacuum environment within the interior 104, as discussed below, the body 102 is designed to withstand the pressure differential between the interior 104 and the region outside the body 102. Additionally, as discussed below, the actuation system 120 is also designed to withstand the reduced pressure P_{I} within the interior 104. Moreover, it is still possible to use a purge gas, although not as much purge gas may be required.

In some implementations, the pressure P_{I} in the interior 104 is held within an acceptable range ΔP of an operating pressure P_{O}. The operating pressure P_{O} can be at or below about 16 kilopascals (kPa). The pressure outside the body 102 is on the order of one atmosphere (atm), which is about 101 kPa (or about 760 torr). In some implementations, the pressure P_{I} is held within a range of about 400 Pa of the operating pressure P_{O}, within 133 Pa of the operating pressure P_{O}, or within 13 Pa of the operating pressure P_{O}.

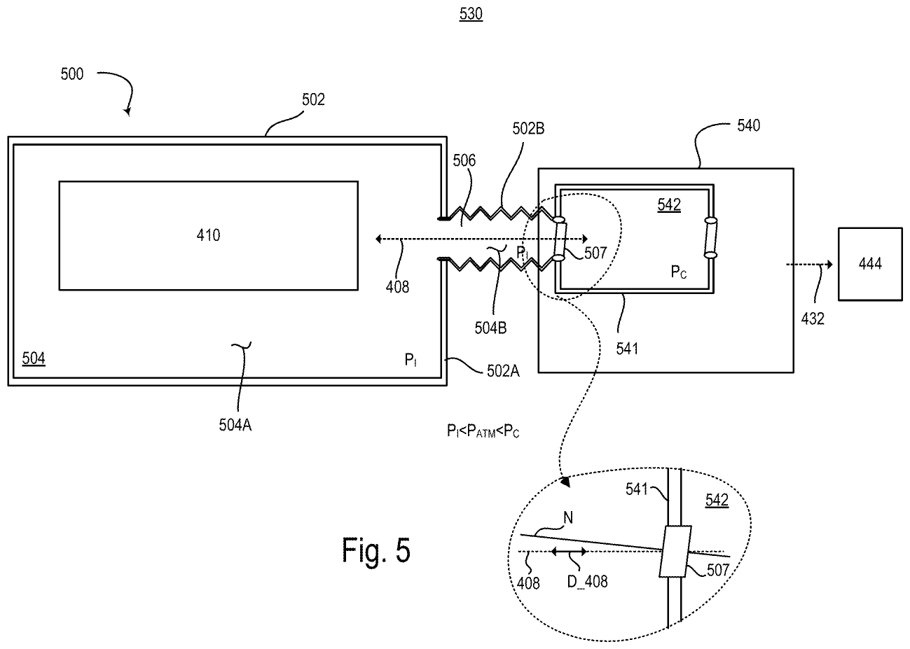

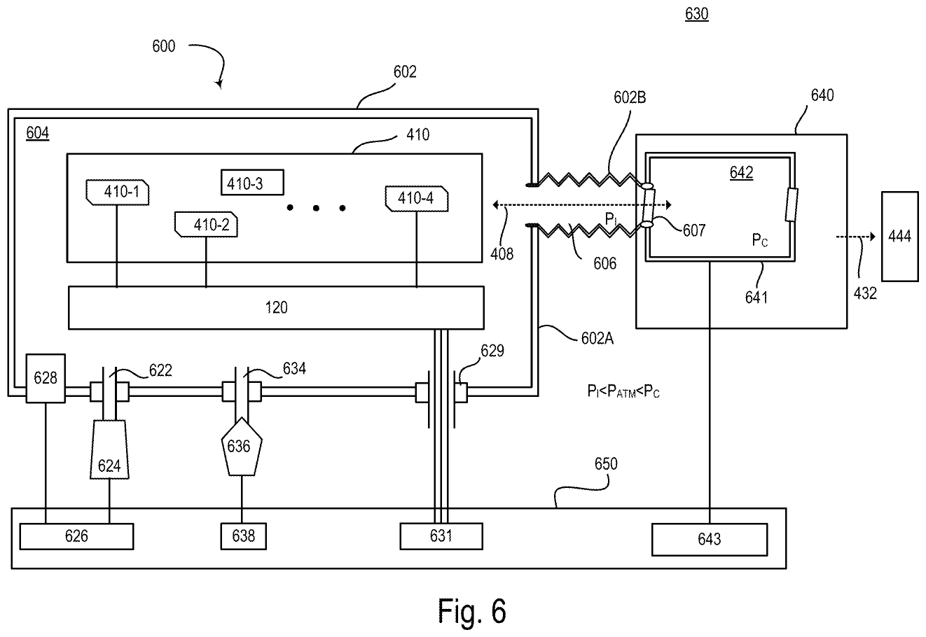

In order to maintain the pressure P_{I} within the interior 104 below atmospheric pressure P_{ATM}, and also to enable the light beam 108 to pass, the optical pathway 106 can include an optical window 107 formed in a wall of the body 102. The optical window 107 is made of a material that is transparent to the wavelength of the light beam 108 and also is configured to withstand a pressure differential between the interior 104 and exterior of the body 102. The optical window 107 can be made of a material that is able to transmit very high pulse energy laser pulses at very short wavelengths (such as DUV wavelengths of 193 nanometers (nm) or 248 nm) and with minimal losses. For example, the optical window 107 can be a crystalline structure made of calcium fluoride (CaF₂), magnesium fluoride (MgF₂), or fused silica. In some implementations, such as shown in FIGS. 5 and 6, the optical window has a normal to its surface that is not parallel with the direction of the light beam 108 to prevent unwanted reflections of the light beam 108 from traveling along the path of the light beam 108.

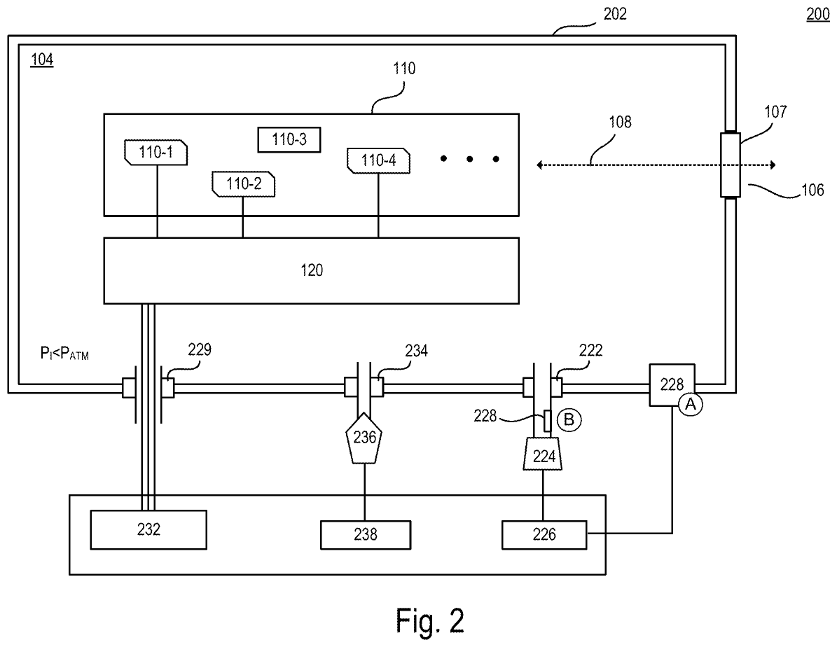

Referring to FIG. 2, the spectral feature adjuster 100 is implemented as spectral feature adjuster 200. The spectral feature adjuster 200 includes a body 202 that is made of a solid non-reactive material that can withstand the pressure differential between the interior pressure P_{I} and the exterior pressure P_{ATM}. The body 202 can be made in several parts that are hermetically sealed using suitable sealing devices such as O-rings or gaskets. The body 202 can be machinable to enable communications between the exterior and the interior 104 to pass through the body 202.

For example, the communications can be enabled by feedthroughs or vacuum ports. Communications that pass through the body 202 can be fluid-based (for flowing gases into or out of the interior 104). An example of a fluid-based communication passing through the body 202 is a vacuum port for pumping matter out of the interior 104 or a port for passing a purge gas into the interior 104. Communications that pass through the body 202 can be electromagnetic-based for transmitting electromagnetic signals into and out of the interior 104. An example of an electromagnetic-based communication passing through the body 202 is a feedthrough appropriate for the type of cable that is used to transmit the electromagnetic signal. For example, coaxial, multipin, or power feedthroughs can be in the body 202. Communications that pass through the body 202 can be mechanical-based. For example, motion feedthroughs can be used to provide precise, repeatable movement or coarse positioning. Communications that pass through the body 202 can be thermal-based. For example, the body 202 can include one or more thermocouple feedthroughs designed to transfer signals through a wall of the body 202 by way of thermocouple material pairs. Communications that pass through the body 202 can be optical-based. For example, the body 202 can be fitted with one or more optical windows (such as the optical window 107), each optical window being hermetically sealed and permitting light to pass between the interior 104 and exterior of the body 202.

In some implementations, the body 202 is made up of walls or structures that are made of stainless steel. Examples of communications through the body 202 are discussed next with reference to FIG. 2.

The body 202 is configured with a vacuum port 222 defined in a wall of the body 202. The vacuum port 222 is in fluid communication with the interior 104 and also with a vacuum pump 224 external to the body 202 of the spectral feature adjuster 200. Operation of the vacuum pump 224 is controlled by a pressure control module 226.

The body 202 also receives a pressure sensor 228 configured to measure the pressure P_{I} within the interior 104 of the body 202. In some implementations, the pressure sensor 228 is mounted inside the interior 104 of the body 202, as shown at A. In other implementations, the pressure sensor 228 is mounted in the gas feedthrough that leads to the vacuum pump 224, as shown at B. Such an arrangement of the pressure sensor 228 in the gas feedthrough that leads to the vacuum pump 224 ensures that the pressure sensor 228 is more protected from the reflections of and stray rays produced by the light beam 108. The pressure sensor 228 can be a light-based oxygen (O₂) sensor such as an optical dissolved oxygen sensors by Mettler Toledo.

The body 202 includes an actuation interface 229 that provides a feedthrough (that is, a hermetically-sealed link or pathway) for any communications between components of the actuation system 120 and an external spectral feature control module 232. Such communications can be electrical or mechanical. Thus, the actuation interface 229 can include one or more hermetically-sealed feedthroughs, with each feedthrough corresponding to a specific communication or corresponding to a communication with a particular component of the actuation system 120.

If a purge gas is used in the interior 104, then the body 202 also includes a purge port 234 that provides a fluid path to a source 236 of purge gas. The purge gas can be released into the interior 104 through the purge port 234 under control of a purge gas control module 238 (which can include one or more fluid control valves). The purge gas can be any non-reactive gas such as nitrogen (N₂), Neon (Ne), Argon (Ar), or carbon dioxide (CO₂). Moreover, because the interior 104 is held at sub-atmospheric pressure, it is possible to avoid using an inert gas such as helium as the purge gas.

Referring to FIG. 3, in some implementations, the actuation system 120 is configured as an actuation system 320 that includes, for each actuatable optical element 110-i, an actuator 320-i configured to adjust a physical aspect of that actuatable optical element 110-i. For example, the actuation system 320 includes actuators 320-1, 320-2, and 320-4 respectively coupled to optical element 110-1, 110-2, and 110-4. The link between the actuator 320-i and its respective optical element 110-i can be physical. For example, the optical element 110-1 can be mounted on a moveable mount that is the actuator 320-1. Such mount can be rotatable, translatable, or both rotatable and translatable. As another example, the optical element 110-2 can be mounted to a device that changes a shape of the optical element 110-2 for example, by bending.

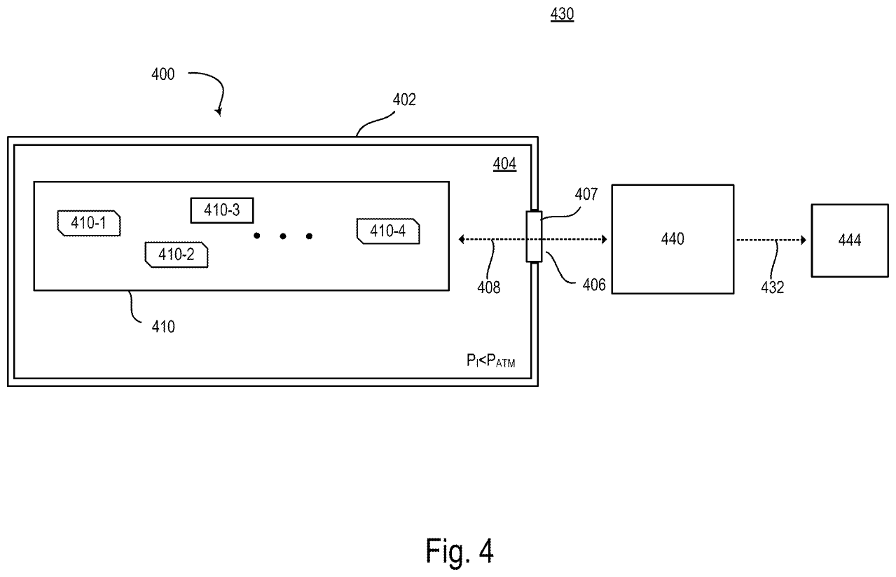

Referring to FIG. 4, an apparatus 430 includes a spectral feature adjuster 400 configured to receive a pre-cursor light beam 408 generated by a gas discharge system 440. Similar to the spectral feature adjuster 100, the spectral feature adjuster 400 includes a body 402 defining an interior 404. The spectral feature adjuster 400 includes at least one optical pathway 406 defined in the body 402, the optical pathway 406 configured to be transparent to the pre-cursor light beam 408 having a wavelength in the ultraviolet range. Thus, the optical pathway 406 is transparent to a light beam having a wavelength between about 10 nanometers (nm) to about 400 nm or in the DUV range, for example, from about 100 nm to about 400 nm. The optical pathway 406 can be fitted with an optical window 407 similar to the optical window 107.

The spectral feature adjuster 400 includes a set 410 of optical elements 410-i, where i is a positive integer. In this example, five optical elements 410-1, 410-2, 410-3, 410-4, 410_5 are shown (that is, i=5), but the set 410 can include fewer than five or more than five optical elements 410-i. Each optical element 410-i in the set 410 is configured to optically interact with the pre-cursor light beam 408. This means that the pre-cursor light beam 408 is optically modified by the interaction with each optical element 410-i. Thus, for example, the light beam 408 can be refracted, reflected, deflected, diffracted, transmitted, expanded or contracted, or magnified due to its interaction with an optical element 410-i. Each optical element 410-i in the set can be distinct from the other optical elements 410-i in the set. As discussed above, one or more of the optical elements 410-i can be refractive optical elements such as prisms, reflective optical elements such as mirrors or beam splitters, and/or diffractive optical elements such as gratings. In operation, the pre-cursor light beam 408 is directed to the spectral feature adjuster 400 which makes adjustments to the pre-cursor light beam 408 based on how the pre-cursor light beam 408 optically interacts with the optical elements 410-i. In this way, the spectral feature adjuster 400 modifies one or more spectral features (such as bandwidth or wavelength) of the pre-cursor light beam 408.

The gas discharge system 440 is configured to produce a light beam 432 from the pre-cursor light beam 408. The light beam 408 can be a light beam that emits light not in a continuous mode, but rather in the form of optical pulses. In this way, the light beam 432 output from the gas discharge system 440 is also a pulsed light beam 432. The light beam 432 can be provided to an apparatus 444 such as a photolithography exposure apparatus for patterning of a substrate W or it can be subjected to further optical processing (such as optical amplification, coherency reduction, etc.) before being used in the apparatus.

Referring to FIG. 5, in some implementations, the apparatus 430 is designed as apparatus 530, which includes a spectral feature adjuster 500 configured to receive the pre-cursor light beam 408 generated by a gas discharge system 540. The gas discharge system 540 includes a gas discharge body 541 that defines a gas discharge chamber 542. The gas discharge system 540 can include other components not shown in FIG. 5 such as a second gas discharge body and chamber as well as beam modification optics. The gas discharge system 540 outputs the light beam 432 for use by the photolithography exposure apparatus 444.

The spectral feature adjuster 500 includes a body 502 that includes a primary body 502A configured to house the set 410 of optical elements 410-i. The body 502 includes a secondary body 502B that is a motion dampening device between the primary body 502A and the gas discharge body 541 that defines the gas discharge chamber 542. The interior 504 therefore extends from a primary interior 504A (defined by the primary body 502A) and a secondary interior 504B (defined by the secondary body 502B). The interior 504B of the motion dampening device 502B and the interior 504A of the primary body 502A are in fluid communication with each other such that the interior 504B of the motion dampening device 502B is at the same pressure (P_{I}) as the interior 504A of the primary body 502A. The light beam 408 passes through the secondary interior 504B while traveling along the optical pathway 506. Thus, the interior 504B of the motion dampening device 502B provides at least part of the optical pathway 506 between the gas discharge chamber 542 and the interior 504.

The optical pathway 506 includes an optical window 507 that is between the motion dampening device 502B and the gas discharge chamber 542. The interior of the secondary body 502B extends from the optical window to the interior 504. The optical window 507 provides a hermetic separation between the interior 504 of the body 502 and the gas discharge chamber 542. In this implementation, the optical window 507 is fitted in the gas discharge body 541.

The motion dampening device 502B can be any device that mechanically insulates the body 502 from the gas discharge body 541 so that the effect of vibrations in one of the bodies (such as gas discharge body 541) on the other of the bodies (such as the body 502) is reduced or prevented. For example, vibrations in the gas discharge body 541 are dampened by the motion dampening device 502B and vibrations in the body 502 are dampened by the motion dampening device 502B. In some implementations, the motion dampening device 502B is a bellows. The bellows can also provide compensation to balance thermal expansion and mounting tolerances (for example, height differences or angular offsets) between the body 502 and the gas discharge body 541.

The bellows 502B can be an edge welded bellows 502B, which means that it is welded to the gas discharge body 541 to provide a hermetic seal. Because the bellows 502B is subjected to a pressure differential (P_{I}−P_{ATM}), the bellows 502B can shrink or expand. Accordingly, the walls of the bellows 502B need to be configured to withstand such pressure differential.

As shown in the insert of FIG. 5, the optical window 507 can be specially cut and tilted so that its normal N does not align with (that is, is not parallel with) a path or axial direction D_408 of the light beam 408 when it interacts with the optical window 507.

An implementation 630 of the apparatus 530 showing aspects of control is shown in FIG. 6. In FIG. 6, the spectral feature adjuster 600 is configured to receive the pre-cursor light beam 408 generated by the gas discharge system 640. Similar to the apparatus 530 of FIG. 5, the gas discharge system 640 includes the gas discharge body 641 that defines the gas discharge chamber 642, and the spectral feature adjuster 600 includes the body 602 that includes the primary body 602A configured to house the set 410 of optical elements 410-i. The body 602 includes a secondary body 602B that is the motion dampening device between the primary body 602A and the gas discharge body 641. The interior of the motion dampening device 602B provides at least part of the optical pathway 606 between the gas discharge chamber 642 and the interior 604. The gas discharge system 640 can include other components not shown in FIG. 6.

The apparatus 630 includes a control apparatus 650 in communication with the gas discharge system 640 and the spectral feature adjuster 600. The control apparatus 650 includes various modules 626, 638, 631, 643 that are dedicated to controlling certain aspects of the apparatus 630. Other modules (not shown) may be included in the control apparatus 650 for controlling other aspects of the apparatus 630. Moreover, each of the modules 626, 638, 631, 643 can be co-located or near to the aspect that is being respectively controlled.

The control apparatus 650 can include an optical source control module 643 that is configured to communicate with one or more elements, components, or systems within the gas discharge system 640. The optical source control module 643 can be placed closer to the gas discharge system 640 than to the other modules in the control apparatus 650. For example, the optical source control module 643 can include a power control sub-module for controlling power to one or more of the elements, components, or systems within the gas discharge system 640. As another example, the optical source control module 643 can include a fluid control sub-module for controlling one or more gas components within the gas discharge chamber 642 or any other gas discharge chamber within the gas discharge system 640.

The control apparatus 650 includes a pressure control module 626 that is in communication with a vacuum pump 624 and also to a pressure sensor 628 in the interior 604. The vacuum pump 624 is in fluid communication with the interior 604 of the body 602 by way of a vacuum port 622 defined in the body 602. Operation of the vacuum pump 224 is thereby controlled by the pressure control module 626 based on the measured pressure P_{I} from the pressure sensor 628. The pressure control module 626 is configured to receive the measured pressure P_{I} from the pressure sensor 628 and to determine whether the measured pressure P_{I} is within an acceptable range of an operating pressure P_{O}. As discussed above, the operating pressure P_{O} can be at or below about 16 kilopascals (kPa). In some implementations, the pressure P_{I} is held within a range of about 400 Pa about the operating pressure P_{O}; that is, P_{I} is held to P_{O} +/−200 Pa. In other implementations, the pressure P_{I} is held within a range of about 140 Pa about the operating pressure P_{O}; that is, P_{I} is held to P_{O} +/−70 Pa. In other implementations, the pressure P_{I} is held within a range of about 20 Pa about the operating pressure P_{O}; that is, P_{I} is held to P_{O}+/−10 Pa.

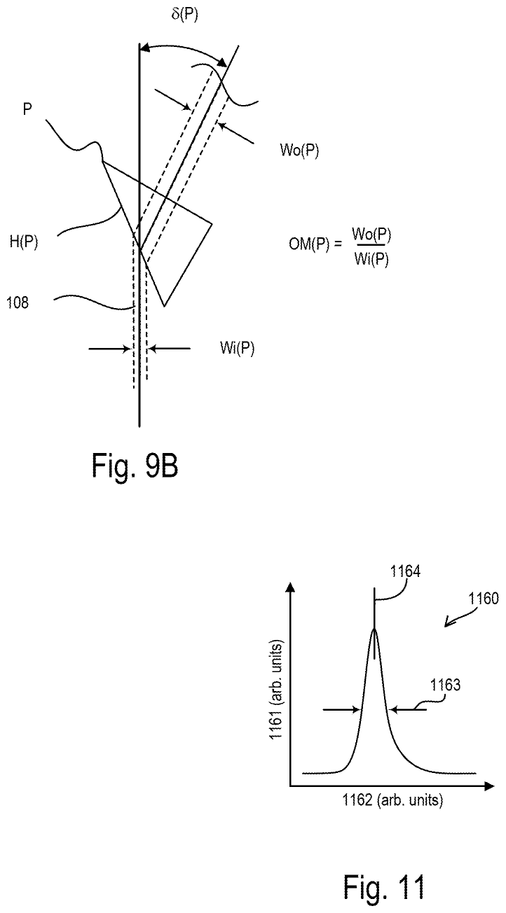

The control apparatus 650 includes a spectral feature control module 631. The spectral feature control module 631 is in communication with the actuation system 120 by way of an actuation interface 629 that provides a communication through the body 602. In some implementations, the actuation interface 629 can be a single feedthrough that provides one or more interfaces for electromagnetic signals between the spectral feature control module 631 and the actuation system 120. In other implementations, the actuation interface 629 can include a plurality of feedthroughs (such as shown in FIGS. 9A and 10B), with each feedthrough providing an interface for electromagnetic signals between the spectral feature control module 631 and one of the actuators (such as any one of the actuators 320-i) within the actuation system 120. It is alternatively possible for communication between the spectral feature control module 631 and the actuation system 120 to be wireless, in which case the actuation interface 629 is not needed.

The spectral feature control module 631 sends one or more signals to the actuation system 120 to instruct the actuation system 120 to adjust or modify one or more optical elements 410-i to thereby adjust at least one spectral feature (such as the wavelength or bandwidth) of the pre-cursor light beam 408. The modification to spectral features of the pre-cursor light beam 408 also modifies the spectral features of the light beam 432, which is produced from the pre-cursor light beam 408. As discussed above, the light beam 432 output from the gas discharge system 640 can be supplied to a photolithography exposure apparatus 444, which uses the light beam 432 for patterning a substrate. The spectral feature control module 631 can therefore be in communication with the photolithography exposure apparatus 444 to receive instructions regarding desired spectral features of the light beam 432. A communication channel (which can be wired or wireless) can be provided between the spectral feature control module 631 and the photolithography exposure apparatus 444. The information that the spectral feature control module 631 receives from the photolithography exposure apparatus 444 can include requests from the photolithography exposure apparatus 444 to alter one or more characteristics of the light beam 432.

For example, the photolithography exposure apparatus 444 sets requirements for the value of one or more spectral features of the light beam 432 so as to produce a desired patterning or lithographic result on the substrate. The photolithography exposure apparatus 444 requires a particular spectral feature or set of spectral features from the light beam 432 depending on the patterning of the substrate.

In one example, the photolithography exposure apparatus 444 requires that each pulse of the light beam 432 have a spectral feature that is selected from among a plurality of discrete spectral features when used to pattern the substrate. It may be desirable for the wavelength of the light beam 432 to change among a set of discrete and distinct values on a pulse-to-pulse basis. This can mean that the wavelength changes for each adjacent and consecutive pulse. Alternatively, the wavelength changes for every other pulse (thus, the wavelength remains at one discrete value for two consecutive pulses and another discrete value for two consecutive pulses, and so forth).

Changing the wavelength can yield a valuable result, for example, from the standpoint of the photolithography exposure apparatus 444. In particular, chromatic aberration on the light beam 432 as it traverses the photolithography exposure apparatus 444 can cause a correlation between the wavelength of the light beam 432 and the location of a focal plane (along the axial direction, which is orthogonal to an image plane of the substrate) of the pulse of the light beam 432 at the substrate. And, it may be desirable to change the focal plane of the light beam 432 when it interacts with or impinges upon the substrate. Accordingly, by changing the wavelength of the light beam 432, the focal plane of the light beam 432 at the substrate in the photolithography exposure apparatus 444 can be adjusted. In this example, the photolithography exposure apparatus 444 instructs the spectral feature control module 631 to adjust the wavelength in the manner required for such patterning of the substrate.

The control apparatus 650 can include a purge gas control module 638 that is configured to control one or more fluid control valves that adjust an amount of purge gas supplied from a source 636 of purge gas. The purge gas is supplied to the interior 604 by way of a purge port 634 that provides fluid communication into interior 604 of the body 602. As discussed above, the purge gas can be any non-reactive gas such as nitrogen (N₂). Moreover, because the interior 604 is held at sub-atmospheric pressure, it is possible to avoid using an inert gas such as helium as the purge gas.

Although the purge port 634 is shown as being formed in the primary body 602A it is alternatively possible to arrange the purge port 634 in the secondary body 602B (the bellows).

The control apparatus 650 and each of the modules (such as modules 626, 638, 631, 643) include one or more of digital electronic circuitry, computer hardware, firmware, and software. The control apparatus 650 can include memory, which can be read-only memory and/or random-access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks. The control apparatus 650 and each of the modules (such as modules 626, 638, 631, 643) can also include one or more input devices (such as a keyboard, touch screen, microphone, mouse, hand-held input device, etc.) and one or more output devices (such as a speaker or a monitor).

The control apparatus 650 and each of the modules (such as modules 626, 638, 631, 643) include one or more programmable processors, and one or more computer program products tangibly embodied in a machine-readable storage device for execution by a programmable processor. The one or more programmable processors can each execute a program of instructions to perform desired functions by operating on input data and generating appropriate output. Generally, the processor receives instructions and data from memory. Any of the foregoing may be supplemented by, or incorporated in, specially designed ASICs (application-specific integrated circuits).

Each module and each of the modules 626, 638, 631, 643 includes a set of computer program products executed by one or more processors such as the processors. Moreover, any of the modules 626, 638, 631, 643 can access data stored within the memory. Each module 626, 638, 631, 643 can receive data from other components and then analyze such data as needed. Each module 626, 638, 631, 643 can be in communication with one or more other modules.

Although the control apparatus 650 (and the modules 626, 638, 631, 643) are represented as boxes (in which all of its components can be co-located), it is possible for the control apparatus 650 or any of the modules 626, 638, 631, 643 to be made up of components that are physically remote from each other. For example, the spectral feature control module 631 can be physically co-located with the body 602.

Any of the modules 626, 638, 631, 643 can communicate with each other as well. In some implementations, the pressure control module 626 is in communication with the optical source control module 643. For example, information can be provided from the pressure control module 626 to the optical source control module 643. Such information can provide an indication of a failure of the vacuum pump 624 to the optical source control module 643 to enable a rapid shutdown or stoppage of the optical source control module 643. In other example, the optical source control module 643 can provide the value of the operating pressure P_{O} to the pressure control module 626. The spectral feature control module 631 can directly communicate with the optical source control module 643. Moreover, the pressure control module 626 and the purge gas control module 638 can both directly communicate with the spectral feature control module 631.

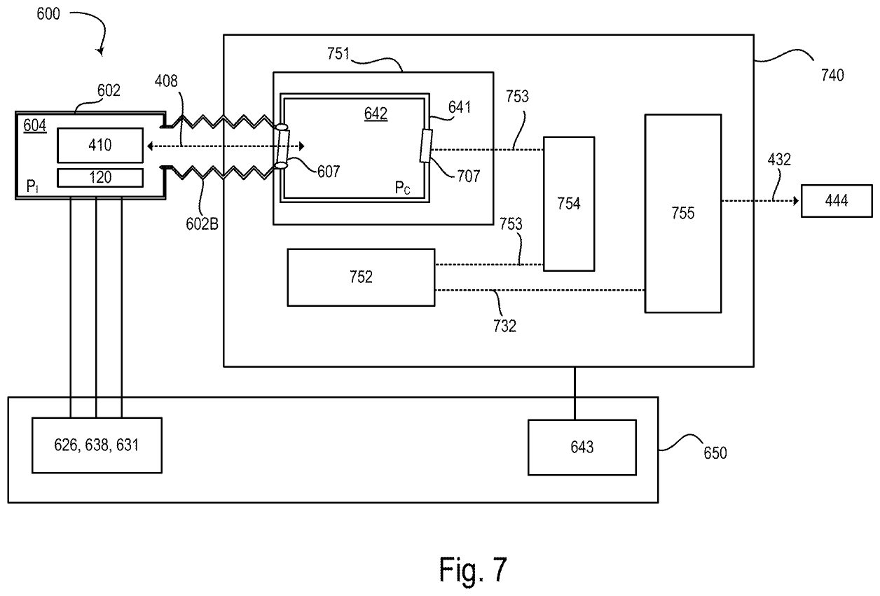

Referring to FIG. 7, an implementation of the gas discharge system 640 that is a two-stage gas discharge system 740 is shown. The two-stage gas discharge system 740 includes a first gas discharge stage 751 that includes the gas discharge body 641 that defines the gas discharge chamber 642 and a second gas discharge stage 752. The gas discharge system 740 acts as a light source that produces the light beam 432 of optical pulses to the apparatus 444.

The first gas discharge stage 751 acts as a master oscillator (MO) and the second gas discharge stage 752 acts as a power amplifier (PA). The MO 751 provides a seed light beam 753 to the PA 752 by way of a set of power optics 754. The MO 751 typically includes a gain medium in which amplification occurs and an optical feedback mechanism such as an optical resonator. The PA 752 typically includes a gain medium in which amplification occurs when seeded with the seed laser beam 753 from the MO 751. If the PA 752 is designed as a regenerative ring resonator then it is described as a power ring amplifier (PRA) and in this case, enough optical feedback can be provided from the ring design. The spectral feature adjuster 600 receives the pre-cursor light beam 408 from the MO 751 to enable fine tuning of the spectral features such as the center wavelength and the bandwidth of the pre-cursor light beam 408 at relatively low output pulse energies. The PA 752 receives the seed light beam 753 from the MO 751 (by way of the power optics 754) and amplifies the seed light beam 753 to produce an amplified light beam 732 to attain the necessary power for output to use in photolithography by the photolithography exposure apparatus 444. The amplified light beam 732 is directed through a set of output optics 755 that can include one or more pulse stretchers, optical shutters, or an analysis module, and the output of the set of output optics 755 is the light beam 432 directed to the photolithography exposure apparatus 444.

The gas discharge chamber 642 of the MO 751 houses two elongated electrodes, a laser gas that serves as the gain medium, and a fan circulating the gas between the electrodes. A laser resonator is formed between the spectral feature adjuster 600 on one side of the gas discharge chamber 642 and an output coupler 707 (such as a partially transmissive optical element) on a second side of the gas discharge chamber 642 to output the seed light beam 753 to the PA 752.

The PA 752 includes a gas discharge chamber as well, and if the PA 752 is a regenerative ring amplifier, the PA 752 also includes a beam reflector or beam turning device that reflects the light beam back into its gas discharge chamber to form a circulating path. The PA gas discharge chamber also includes its own pair of elongated electrodes, a laser gas that serves as the gain medium, and a fan for circulating the gas between the electrodes. The seed light beam 753 is amplified by repeatedly passing through the gas discharge chamber of the PA 752. The PA 752 can include a beam modification optical system that provides a way (for example, a partially-reflecting mirror) to in-couple the seed light beam 753 and to out-couple a portion of the amplified radiation from the PA 752 to form the amplified light beam 732.

The laser gas used in the gas discharge chamber 642 of the MO 751 and the gas discharge chamber of the PA 752 can be any suitable gas for producing a laser beam around the required wavelengths and bandwidth. For example, the laser gas include argon fluoride (ArF), which emits light at a wavelength of about 193 nm, or krypton fluoride (KrF), which emits light at a wavelength of about 248 nm.

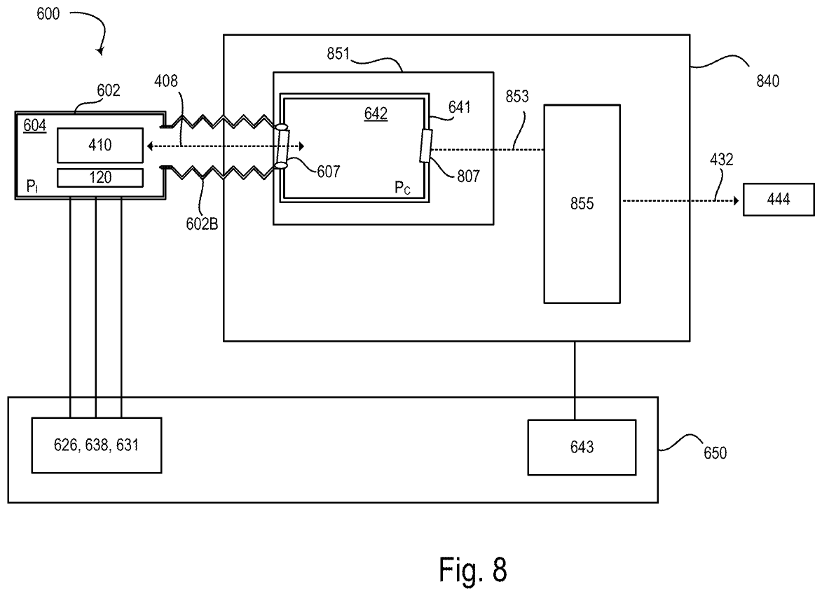

Referring to FIG. 8, an implementation of the gas discharge system 640 that is a single stage gas discharge system 840 is shown. The single stage gas discharge system 840 includes a gas discharge stage 851 that includes the gas discharge body 641 that defines the gas discharge chamber 642. The gas discharge system 840 acts as a light source that produces the light beam 432 of optical pulses to the apparatus 444. The gas discharge chamber 642 houses two elongated electrodes, a laser gas that serves as the gain medium, and a fan circulating the gas between the electrodes. A laser resonator is formed between the spectral feature adjuster 600 on one side of the gas discharge chamber 642 and an output coupler 807 (such as a partially transmissive optical element) on a second side of the gas discharge chamber 642 to output a light beam 853. The laser gas used in the gas discharge chamber 642 can be any suitable gas for producing a laser beam around the required wavelengths and bandwidth. For example, the laser gas include argon fluoride (ArF), which emits light at a wavelength of about 193 nm, or krypton fluoride (KrF), which emits light at a wavelength of about 248 nm.

The gas discharge system 840 also includes a set of optics 855 that can include one or more pulse stretchers, optical shutters, or an analysis module, and the output of the set of output optics 855 is the light beam 432 directed to the photolithography exposure apparatus 444.

Referring to FIG. 9A, an implementation 900 of the spectral feature adjuster 100 is shown that includes a body 902 defining an interior 904 that houses a set 910 of five optical elements 910-1, 910-2, 910-3, 910-4, 910-5 (generally referred to as 910-i, where i can be 1, 2, 3, 4, or 5) and an actuation system 920. The actuation system 920 includes an actuator 920-1, 920-2, 920-3, 920-4, 920-5 (generally referred to as 920-i, where i can be 1, 2, 3, 4, or 5) for each respective actuatable optical element. Each of the optical elements 910-i is arranged to interact with the light beam 108 that traverses the optical pathway 906 into the interior 904.

The set 910 of five optical elements includes a dispersive optical element 910-1, which can be a grating, and a beam expander made up of refractive optical elements 910-2, 910-3, 910-4, 910-5, which can be prisms. The grating 910-1 can be a reflective grating that is designed to disperse and reflect the light beam 108. Accordingly, the grating 910-1 is made of a material that is suitable for interacting with the light beam 108 having a wavelength in the DUV range. Each of the prisms 910-2, 910-3, 910-4, 910-5 is a transmissive prism that acts to disperse and redirect the light beam 108 as it passes through the body of the prism. Each of the prisms 910-2, 910-3, 910-4, 910-5 can be made of a material such as calcium fluoride that permits the transmission of the wavelength of the light beam 108.

The light beam 108 enters the interior 904 by way of the optical pathway 906, then travels through prism 910-5, then prism 910-4, then prism 910-3, then prism 910-2, in that order, prior to impinging upon a diffractive surface 911-1 of the grating 910-1. With each passing of the beam 108 through a prism 910-5, 910-4, 910-3, 910-2, the light beam 108 is optically magnified and redirected (refracted at an angle) toward the next optical component. The light beam 108 is diffracted and reflected from the grating 910-1 back through the prism 910-2, the prism 910-3, the prism 910-4, and the prism 910-5, in that order, prior to passing back through the optical pathway 906 and out of the interior 904. With each passing through the consecutive prisms 910-2, 910-3, 910-4, 910-5 from the grating 910-1, the light beam 108 is optically compressed as it travels toward the optical pathway 906.

As shown in FIG. 9B, the rotation of a particular prism P (which can be any of the prisms 910-2, 910-3, 910-4, 910-5) changes an angle of incidence at which the light beam 108 impinges upon an entrance surface H(P) of that rotated prism P. Two local optical qualities, optical magnification OM(P) and a beam refraction angle δ(P) of the light beam 108 through that rotated prism P are functions of the angle of incidence of the light beam 108 impinging upon the entrance surface H(P) of that rotated prism P. The optical magnification OM(P) of the light beam 108 through the prism P is the ratio of a transverse width Wo(P) of the light beam 108 exciting that prism P to a transverse width Wi(P) of the light beam 108 entering that prism P. Moreover, with reference again to FIG. 9A, a change in the local optical magnification OM(P) of the light beam 108 at one or more of the prism P causes an overall change in the optical magnification OM of the light beam 108, and a change in the local beam refraction angle δ(P) through one or more of the prisms P causes an overall change in an angle of incidence of the light beam 108 at the diffractive surface 911-1 of the grating 910-1. The wavelength of the light beam 108 can be adjusted by changing the angle of incidence at which the light beam 108 impinges upon the diffractive surface 911-1 of the grating 910-1 while the bandwidth of the light beam 108 can be adjusted by changing the optical magnification OM of the light beam 108.

The grating 910-1 can be a high blaze angle Echelle grating, and the light beam 108 incidence on the grating 910-1 at any angle of incidence that satisfies the grating equation will be reflected and diffracted. The grating equation provides the relationship between the spectral order of the grating 910-1, the diffracted wavelength (that is, the wavelength of the diffracted light beam), the angle of incidence of the light beam 108 onto the diffractive surface 911-1 of the grating 910-1, the angle of exit of the light beam 108 diffracted off the diffractive surface 911-1 of the grating 910-1, the vertical divergence of the light beam 108 incident onto the diffractive surface 911-1 of the grating 910-1, and a groove spacing of the diffractive surface 911-1 of the grating 910-1. If the grating 910-1 is used such that the angle of incidence of the light beam 108 onto the grating 910-1 is equal to the angle of exit of the light beam 108 from the grating 910-1, then the grating 910-1 and the set of prisms 910-2, 910-3, 910-4, 910-5 are considered to be arranged in a Littrow configuration and the wavelength of the light beam 108 reflected from the grating 910-1 is the Littrow wavelength.

Each of the actuators 920-1, 920-2, 920-3, 920-5 is connected to its respective optical element 910-1, 910-2, 910-3, 910-5. Each actuator 920-1, 920-2, 920-3, 920-5 is a mechanical device for moving or controlling the respective optical element. The actuators 920-2, 920-3, 920-5 receive energy from the spectral feature control module 631 and convert that energy into some kind of motion that is imparted to the respective optical element. For example, the actuators 920-2, 920-3, 920-5 can be any one of force devices and rotation stages for rotating the respective prism 910-2, 910-3, 910-5. The actuators 920-1, 920-2, 920-3, 920-5 can include, for example, motors such as linear stepper motors, rotary stepper motors, valves, pressure-controlled devices, piezoelectric devices, hydraulic actuators, and voice coils. In this implementation, the prism 910-4 is kept stationary or not physically coupled to an actuator. The actuator 920-1 can be a beam correction device that is configured to bend the optical element 910-1 (which is a grating in this implementation).

Each of the prisms 910-2, 910-3, 910-4, 910-5 are right-angled prisms through which the pulsed light beam 108 is transmitted. The propagation direction of the light beam 108 inside the interior 904 and through the prisms 910-2, 910-3, 910-4, 910-5 is in an X_{S}-Y_{S} plane of the spectral feature adjuster 900. The prism 910-2 is physically coupled to the actuator 920-2 that rotates the prism 910-2 about an axis that is parallel with the Z_{S} axis of the spectral feature adjuster 900. The prism 910-3 is physically coupled to the actuator 920-3 that rotates the prism 910-3 about an axis that is parallel with the Z_{S} axis of the spectral feature adjuster 900.

Additionally, the prism 910-5 is physically coupled to an actuator 920-5 that is configured to rotate the prism 910-5 about an axis that is parallel with the Z_{S} axis of the spectral feature adjuster 900. The actuator 920-5 can include a rotary stepper motor that has a rotation shaft and a rotation plate fixed to the rotation shaft and the prism 910-5 is fixed to the rotation plate. The rotation shaft and the rotation plate rotate about a shaft axis that is parallel with the Z_{S} axis, and this causes the prism 910-5 to rotate about its prism axis that is parallel with the Z_{S} axis. The rotary stepper motor can be a direct drive stepper motor that is a conventional electromagnetic motor that uses a built-in step motor functionality for position control. In other implementations in which a higher resolution in motion may be needed, the stepper motor can use a piezoelectric motor technology. The rotary stepper motor can be a rotary stage that is controlled with a motor controller using a variable-frequency drive control method to provide rapid rotation of the prism 910-5.

In this implementation, as shown in FIG. 9A, and also shown in FIGS. 10A and 10B, each actuator 920-2, 920-3, 920-5 is in communication with the spectral feature control module 631 by way of a respective actuation interface 929-2, 929-3, 929-5, each actuation interface providing a communication through the body 902. For example, wires from each actuator 920-2, 920-3, 920-5 pass through a hermetically-sealed electrical feedthrough at the respective actuation interface 929-2, 929-3, 929-5. It is alternatively possible for each actuator 920-2, 920-3, 920-5 to be in communication with the spectral feature control module 631 by way of a single actuation interface 929 that provides a single communication through the body 902. All of the wires from each actuator 920-2, 920-3, 920-5 pass through a single hermetically-sealed electrical feedthrough at the actuation interface 929.

The actuation interfaces 929-2, 929-3, 929-5 can provide the wired communication that is needed to control the respective actuator 920-2, 920-3, 920-5. This communication includes both a power signal and a drive signal. The power signal may need to be sent through a dedicated hermetically-sealed electrical feedthrough so as to reduce noise that can interfere with the drive signal. The dedicated electrical feedthrough or feedthroughs for the power signals can be configured with additional electrical insulation to further reduce noise interference at the drive signal. Moreover, the wired communications that are provided through the actuation interfaces 929-2, 929-3, 929-5 can be shielded from stray radiation that is produced from the light beam 108 traveling through the interior 904 and interacting with the optical elements 910-i to avoid outgassing of any insulating wire jackets that are used for such transmissions. For example, heavy stainless steel braided wire conduit can be used to provide the wired communications from the actuators 920-2, 920-3, 920-5 through the respective actuation interfaces 929-2, 929-3, 929-5.

The actuator 920-1 is in communication with an external control device 631-1 (which can be a part of the spectral feature control module 631 if automated or can be a human operator if manually controlled) by way of a mechanical actuation interface 929-1. The mechanical actuation interface 929-1 includes a mechanical feedthrough that enables a through-the-wall rotation mechanism for controlling the actuator 920-1.

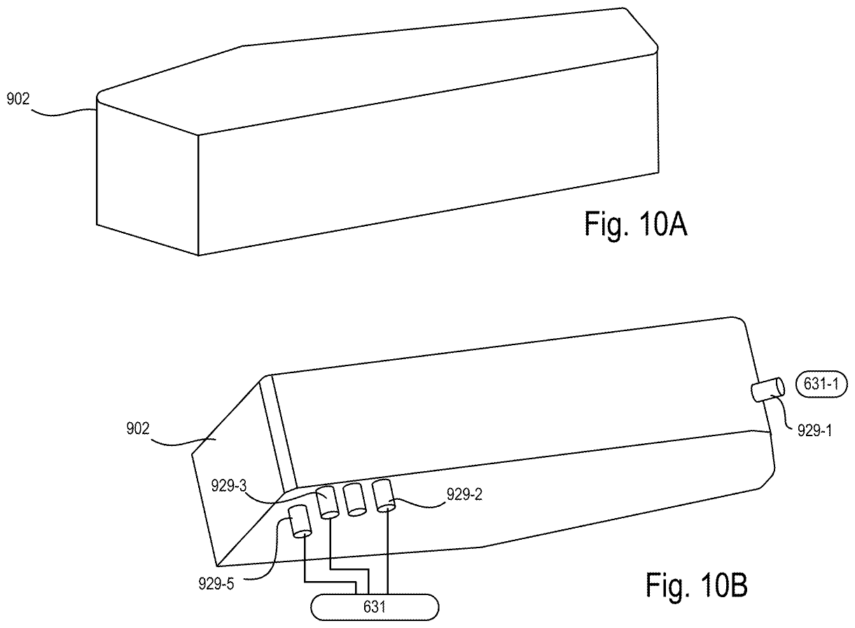

Referring to FIG. 11, the spectral feature of the light beam 108 that is controlled by any of the spectral feature adjusters 100, 200, 300, 400, 500, 600 discussed herein, is any aspect or representation of an optical spectrum 1160 of the light beam 108. The optical spectrum 1160 can be referred to as an emission spectrum. The optical spectrum 1160 contains information on how the optical energy, spectral intensity, or power of the light beam 108 is distributed over different wavelengths. The optical spectrum 1160 of the light beam 108 is depicted in the form of a diagram or graph in which the spectral intensity 1161 (not necessarily with an absolute calibration) is plotted as a function of the wavelength 1162 (or optical frequency, which is inversely proportional to the wavelength).

One example of a spectral feature is a bandwidth, which is a measure of a width 1163 of optical spectrum 1160. This width 1163 can be given in terms of wavelength or frequency of the laser light. Any suitable mathematical construction (that is, metric) related to the details of the optical spectrum 1160 can be used to estimate a value that characterizes the bandwidth of the light beam 108. For example, the full width of the optical spectrum at a fraction (X) of the maximum peak intensity of the optical spectrum 1160 (referred to as FWXM) can be used to characterize the bandwidth of the light beam 108. As another example, the width of the optical spectrum 1160 that contains a fraction (Y) of the integrated spectral intensity (referred to as EY) can be used to characterize the bandwidth of the light beam 108. Another example of a spectral feature is a wavelength, which can be a wavelength value 1164 of the optical spectrum 1160 at a particular (such as a maximum) spectral intensity.

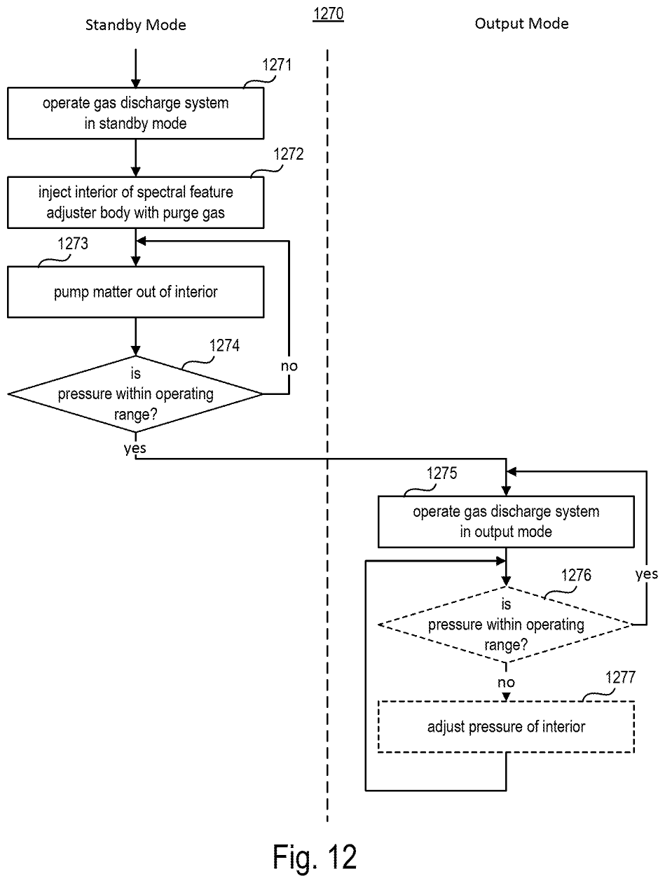

Referring to FIG. 12, a procedure 1270 is performed for controlling a pressure within a spectral feature adjuster. Reference is made to the spectral feature adjuster 600 when discussing the procedure 1270 but the procedure 1270 can be applied by any of the spectral feature adjusters 100, 200, 300, 400, 500, or 600 described herein. The procedure 1270 can be performed by the control apparatus 650.

The procedure 1270 begins after the gas discharge system 640 is ready to restart from a reboot or standby mode. In this situation, the gas discharge system 640 is ready to operate but the spectral feature adjuster 600 is not yet ready for operation. In standby mode, the gas discharge system 640 is therefore waiting and ready for operation and the optical source control module 643 operates the gas discharge system 640 in standby mode (1271). For example, gas fills and purges are active during standby mode and the fan is configured to continue to circulate the gas between the electrodes of any discharge chambers in the system 640. However, the gas discharge system 640 is not producing the light beam 432 for use by the apparatus 444 while in standby mode (and thus, the electrodes are not providing energy to the laser gas or gases in the discharge chambers of the gas discharge system 640).

After the reboot of the gas discharge system 640 (while the gas discharge system 640 is still in standby mode 1271), the spectral feature adjuster 600 has not yet been prepared for operation. That is, the pressure within the interior 604 is not being controlled and purge gas is not being used to purge the interior 604. Thus, the spectral feature adjuster 600 is sealed and the purge gas control module 638 operates the purge gas source 636 to inject the interior 604 with the purge gas (such as N₂) (1272). The purge gas can be used to expel other unwanted gaseous components (such as oxygen) from the interior 604 of the body 602 that may have entered the interior 604 before the reboot of the gas discharge system 640.

The pressure control module 626 operates the vacuum pump 624 to pump matter out of the interior 604 (1273). The pressure control module 626 determines whether the pressure P_{I} is within the operating range ΔP of the operating pressure P_{O} (1274) by, for example, analyzing the measured pressure P_{I} from the pressure sensor 628.

If the pressure control module 626 determines that the pressure P_{I} is not within the operating range ΔP of the operating pressure P_{O} (1274), then it continues to operate the vacuum pump 624 to pump matter out of the interior 604 (1273). If the pressure control module 626 determines that the pressure P_{I} is within the operating range ΔP of the operating pressure P_{O} (1274), then the optical source control module 643 switches from operating the gas discharge system 640 in standby mode (1271) to operating the gas discharge system 640 in output mode (1275). For example, the pressure control module 626 sends a signal to the optical source control module 643 to instruct the optical source control module 643 to begin operating the gas discharge system 640 in output mode.

Operation of the gas discharge system 640 in output mode (1275) includes producing the pre-cursor light beam 408, adjusting a spectral feature of the pre-cursor light beam 408 by interaction with the spectral feature adjuster 600, and forming the light beam 432 from the pre-cursor light beam 408 for use by the apparatus 444. During operation of the gas discharge system 640 in output mode (1275), and because the pre-cursor light beam 408 is interacting with the optical elements 410-i of the set 410 in the spectral feature adjuster 600, the pressure within the interior 604 of the body 602 of the spectral feature adjuster 600 needs to be maintained with the operating range ΔP of the operating pressure P_{O}. This is because the spectral features (such as bandwidth and wavelength) of the pre-cursor light beam 408 are directly impacted or altered by changes in the pressure within the interior 604 through which the pre-cursor light beam 408 travels.

The pressure control module 626 determines whether the pressure P_{I} within the interior 604 of the spectral feature adjuster body 602 is outside the operating range ΔP of the operating pressure P_{O} (1276). For example, the pressure control module 626 compares the measured pressure P_{I} from the pressure sensor 628 to the operating pressure P_{O}. If the pressure control module 626 determines that the pressure P_{I} within the interior 604 is outside the operating range ΔP of the operating pressure P_{O} (1276), then pressure within the interior 604 of the spectral feature adjuster body 602 is adjusted (1277).

For example, if the pressure control module 626 determines that the pressure P_{I} within the interior 604 of the spectral feature adjuster body 602 is greater than the operating range ΔP of the operating pressure P_{O} (1276), then the pressure control module 626 can send a signal to the vacuum pump 624 to pump matter out of the interior 604 of the spectral feature adjuster body 602. As another example, if the pressure control module 626 determines that the pressure P_{I} within the interior 604 of the spectral feature adjuster body 602 is below the operating range ΔP of the operating pressure P_{O} (1276), the pressure control module 626 can send a signal to the vacuum pump 624 to stop pumping matter out of the interior 604 of the spectral feature adjuster body 602. Or, the pressure control module 626 can request that the vacuum pump 624 or some other pump open in a controlled manner the interior 604 of the spectral feature adjuster body 602 to atmosphere so that the pressure P_{I} within the interior 604 can rise. It is alternatively or additionally possible for the pressure control module 626 to send a signal to the purge gas control module 638 to input more purge gas into the interior 604 by way of the purge port 634.

By controlling the pressure in the spectral feature adjuster 600 to within the operating range both in standby mode (1274) and in output mode (1276), it is possible to maintain certain properties (such as spectral features or energy) of the light beam 432 to within acceptable ranges.

Other implementations are within the scope of the following claims.

Other aspects of the invention are set out in the following numbered clauses.

1. A spectral feature adjuster comprising:

a body defining an interior that is held at a pressure below atmospheric pressure;

at least one optical pathway through the body, the optical pathway being transparent to a light beam having a wavelength in the ultraviolet range;

a set of optical elements within the interior, the optical elements in the set being configured to interact with the light beam, wherein the set of optical elements include one or more actuatable optical elements; and an actuation system within the interior, the actuation system being in communication with the one or more actuatable optical elements and configured to adjust a physical aspect of the one or more actuatable optical elements.

2. The spectral feature adjuster of clause 1, further comprising:

a vacuum port defined in a wall of the body, the vacuum port being in fluid communication with the interior and with a vacuum pump external to the spectral feature adjuster.

3. The spectral feature adjuster of clause 1, further comprising:

a pressure sensor configured to measure a pressure within the interior.

4. The spectral feature adjuster of clause 1, wherein the set of optical elements comprises:

a set of refractive elements; and

a diffractive element.

5. The spectral feature adjuster of clause 4, wherein each refractive element is a prism and the diffractive element is a grating.

6. The spectral feature adjuster of clause 5, wherein the set of refractive elements includes a set of four prisms.

7. The spectral feature adjuster of clause 1, wherein the actuation system includes, for each actuatable optical element, an actuator configured to adjust a physical aspect of that actuatable optical element.

8. The spectral feature adjuster of clause 1, further comprising:

an actuation interface defined in the body, the actuation interface in communication with the actuation system and to a control system external the spectral feature adjuster.

9. The spectral feature adjuster of clause 1, wherein the interior is held at a pressure at or below 16 kilopascals (kPa), at or below 12 kPa, or at or below 8 kPa.

10. The spectral feature adjuster of clause 1, wherein the interior is held within 400 pascals (Pa) of an operating pressure or within 140 Pa of the operating pressure or within 20 Pa of the operating pressure.

11. The spectral feature adjuster of clause 1, wherein the interior lacks helium.

12. The spectral feature adjuster of clause 1, wherein the interior includes a purge gas.

13. The spectral feature adjuster of clause 12, wherein the purge gas includes nitrogen.

14. The spectral feature adjuster of clause 1, wherein the body includes a purge port fluidly communicating the interior with a source of the purge gas.

15. The spectral feature adjuster of clause 1, wherein at least part of the body is defined by a motion dampening device that physically couples to a gas discharge body of the gas discharge chamber, and the optical pathway extends through an interior of the motion dampening device and through an optical port defined in the gas discharge body.

16. The spectral feature adjuster of clause 15, wherein the body is hermetically-sealed and the interior of the motion dampening device is held at the same pressure as the interior of the body.

17. An apparatus comprising:

a gas discharge system including a gas discharge chamber and configured to produce a light beam; and

a spectral feature adjuster in optical communication with a pre-cursor light beam generated by the gas discharge chamber, the spectral feature adjuster comprising:

a body defining an interior that is held at a pressure below atmospheric pressure;

at least one optical pathway defined between the gas discharge chamber and the interior of the body, the optical pathway being transparent to the pre-cursor light beam; and

a set of optical elements within the interior, the optical elements configured to interact with the pre-cursor light beam.

18. The apparatus of clause 17, further comprising a control apparatus in communication with the gas discharge system and the spectral feature adjuster.

19. The apparatus of clause 18, further comprising:

a pressure sensor configured to measure a pressure within the interior.

20. The apparatus of clause 19, wherein the control apparatus includes a pressure module in communication with the pressure sensor and configured to receive the measured pressure and determine whether the measured pressure is within an acceptable range of pressures.

21. The apparatus of clause 20, further comprising a vacuum pump, wherein the spectral feature adjuster comprises a vacuum port defined in the body, the vacuum port being in fluid communication with the interior and with the vacuum pump.

22. The apparatus of clause 21, wherein the pressure module is in communication with the vacuum pump and is configured to control operation of the vacuum pump based, at least in part, on the determination regarding the measured pressure.

23. The apparatus of clause 18, wherein the spectral feature adjuster includes an actuation system within the interior, the actuation system being in communication with one or more optical elements in the interior and configured to adjust a physical aspect of the one or more optical elements to thereby adjust one or more spectral features of the pre-cursor light beam.

24. The apparatus of clause 23, wherein the control apparatus comprises a spectral feature module in communication with the actuation system, the spectral feature module configured to receive estimates of one or more spectral features of the light beam and to adjust a signal to the actuation system based on the received estimates.

25. The apparatus of clause 18, further comprising a source of purge gas in fluid communication with the interior, wherein the control apparatus includes a purge gas module in communication with the purge gas source and configured to control a flow of purge gas from the purge gas source into the interior.

26. The apparatus of clause 17, wherein the gas discharge system includes:

a first gas discharge stage including the gas discharge chamber that is configured to generate a seed light beam from the pre-cursor light beam; and a second gas discharge stage configured to receive the seed light beam and to amplify the seed light beam to thereby produce the light beam from the gas discharge system.

27. The apparatus of clause 26, wherein:

the first gas discharge stage including the gas discharge chamber houses an energy source and contains a gas mixture that includes a first gain medium; and the second gas discharge stage includes a gas discharge chamber housing an energy source and containing a gas mixture that includes a second gain medium.

28. The apparatus of clause 17, wherein the gas discharge chamber houses an energy source and contains a gas mixture that includes a first gain medium.

29. The apparatus of clause 17, wherein the interior is held at a pressure at or below 16 kPa, at or below 12 kPa, or at or below 8 kPa.

30. The apparatus of clause 17, wherein the body comprises a primary body housing the set of optical elements and a motion dampening device between the primary body and a gas discharge body of the gas discharge chamber, the interior of the motion dampening device providing at least part of the optical pathway between the gas discharge chamber and the interior.

31. The apparatus of clause 30, further comprising an optical window between the motion dampening device and the gas discharge chamber, the optical window providing a hermetic separation between the interior of the body and the gas discharge chamber.

32. The apparatus of clause 30, wherein the interior of the motion dampening device and the interior of the body are fluidly open to each other such that the interior of the motion dampening device is at the same pressure as the interior of the body.

33. A method of controlling a spectral feature of a light beam, the method comprising:

while operating a gas discharge system in standby mode:

injecting an interior of a body of a spectral feature adjuster with a purge gas; and

pumping matter out of the interior of the spectral feature adjuster body until the pressure within the interior of the spectral feature adjuster body is below atmospheric pressure;

determining whether the pressure within the interior of the spectral feature adjuster body is within an operating range of pressures; and

if it is determined that the pressure within the interior of the spectral feature adjuster body is within the operating range of pressures, then switching from operating the gas discharge system in the standby mode to operating the gas discharge system in output mode.

34. The method of clause 33, further comprising, while operating the gas discharge system in output mode:

determining whether the pressure within the interior of the spectral feature adjuster body is within an operating range of pressures; and

if it is determined that the pressure within the interior of the spectral feature adjuster body is outside the operating range of pressures, then adjusting pressure of the interior of the spectral feature adjuster body.

35. The method of clause 34, wherein if it is determined that the pressure within the interior of the spectral feature adjuster body is above the operating range of pressures, then adjusting pressure of the interior of the spectral feature adjuster body comprises pumping matter out of the interior of the spectral feature adjuster body.

36. The method of clause 34, wherein if it is determined that the pressure within the interior of the spectral feature adjuster body is below the operating range of pressures, then adjusting pressure of the interior of the spectral feature adjuster body comprises opening in a controlled manner the interior of the spectral feature adjuster body to atmosphere or stopping pumping matter out of the interior of the spectral feature adjuster body.

37. The method of clause 33, wherein the operating range of pressures is centered about an operating pressure that is at or below 16 kPa, at or below 12 kPa, or at or below 8 kPa.

38. The method of clause 33, wherein the operating range of pressures is 400 Pa, 140 Pa, or 20 Pa.

39. The method of clause 33, further comprising, prior to operating the gas discharge system in standby mode, hermetically sealing the interior of the spectral feature adjuster body from a gas discharge cavity of the gas discharge system, the gas discharge cavity being in optical communication with the interior of the spectral feature adjuster of the gas discharge system by way of an optical pathway.

40. The method of clause 39, wherein operating the gas discharge system in output mode comprises directing a pre-cursor light beam between the gas discharge cavity and the interior of the spectral feature adjuster body so that the pre-cursor light beam interacts with optical elements within the interior of the spectral feature adjuster body.

1. A spectral feature adjuster comprising:
a body defining an interior that is held at a pressure below atmospheric pressure;
at least one optical pathway through the body, the optical pathway being transparent to a light beam having a wavelength in the ultraviolet range;
a set of optical elements within the interior, the optical elements in the set being configured to interact with the light beam, wherein the set of optical elements include one or more actuatable optical elements; and
an actuation system within the interior, the actuation system being in communication with the one or more actuatable optical elements and configured to adjust a physical aspect of the one or more actuatable optical elements.

2. The spectral feature adjuster of claim 1, wherein the set of optical elements comprises:
a set of refractive elements; and
a diffractive element.

3. The spectral feature adjuster of claim 2, wherein each refractive element is a prism and the diffractive element is a grating.

4. The spectral feature adjuster of claim 3, wherein the set of refractive elements includes a set of four prisms.

5. The spectral feature adjuster of claim 1, wherein the actuation system includes, for each actuatable optical element, an actuator configured to adjust a physical aspect of that actuatable optical element.

6. The spectral feature adjuster of claim 1, further comprising:
an actuation interface defined in the body, the actuation interface in communication with the actuation system and to a control system external the spectral feature adjuster.

7. The spectral feature adjuster of claim 1, wherein the interior lacks helium.

8. The spectral feature adjuster of claim 1, wherein the interior includes a purge gas.

9. The spectral feature adjuster of claim 1, wherein the body includes a purge port fluidly communicating the interior with a source of the purge gas.

10. The spectral feature adjuster of claim 1, wherein at least part of the body is defined by a motion dampening device that physically couples to a gas discharge body of the gas discharge chamber, and the optical pathway extends through an interior of the motion dampening device and through an optical port defined in the gas discharge body.

11. An apparatus comprising:
a gas discharge system including a gas discharge chamber and configured to produce a light beam; and
a spectral feature adjuster in optical communication with a pre-cursor light beam generated by the gas discharge chamber, the spectral feature adjuster comprising:
a body defining an interior that is held at a pressure below atmospheric pressure;
at least one optical pathway defined between the gas discharge chamber and the interior of the body, the optical pathway being transparent to the pre-cursor light beam; and
a set of optical elements within the interior, the optical elements configured to interact with the pre-cursor light beam.

12. The apparatus of claim 11, further comprising a control apparatus in communication with the gas discharge system and the spectral feature adjuster.

13. The apparatus of claim 12, further comprising:
a pressure sensor configured to measure a pressure within the interior.

14. The apparatus of claim 12, wherein the spectral feature adjuster includes an actuation system within the interior, the actuation system being in communication with one or more optical elements in the interior and configured to adjust a physical aspect of the one or more optical elements to thereby adjust one or more spectral features of the pre-cursor light beam.

15. The apparatus of claim 14, wherein the control apparatus comprises a spectral feature module in communication with the actuation system, the spectral feature module configured to receive estimates of one or more spectral features of the light beam and to adjust a signal to the actuation system based on the received estimates.

16. The apparatus of claim 11, wherein the gas discharge system includes:
a first gas discharge stage including the gas discharge chamber that is configured to generate a seed light beam from the pre-cursor light beam; and
a second gas discharge stage configured to receive the seed light beam and to amplify the seed light beam to thereby produce the light beam from the gas discharge system.

17. The apparatus of claim 16, wherein:
the first gas discharge stage including the gas discharge chamber houses an energy source and contains a gas mixture that includes a first gain medium; and
the second gas discharge stage includes a gas discharge chamber housing an energy source and containing a gas mixture that includes a second gain medium.

18. The apparatus of claim 11, wherein the gas discharge chamber houses an energy source and contains a gas mixture that includes a first gain medium.

19. The apparatus of claim 11, wherein the body comprises a primary body housing the set of optical elements and a motion dampening device between the primary body and a gas discharge body of the gas discharge chamber, the interior of the motion dampening device providing at least part of the optical pathway between the gas discharge chamber and the interior.

20. The apparatus of claim 19, wherein the interior of the motion dampening device and the interior of the body are fluidly open to each other such that the interior of the motion dampening device is at the same pressure as the interior of the body.

21. A method of controlling a spectral feature of a light beam, the method comprising:
while operating a gas discharge system in standby mode:
injecting an interior of a body of a spectral feature adjuster with a purge gas; and
pumping matter out of the interior of the spectral feature adjuster body until the pressure within the interior of the spectral feature adjuster body is below atmospheric pressure;
determining whether the pressure within the interior of the spectral feature adjuster body is within an operating range of pressures; and
if it is determined that the pressure within the interior of the spectral feature adjuster body is within the operating range of pressures, then switching from operating the gas discharge system in the standby mode to operating the gas discharge system in output mode.

22. The method of claim 21, further comprising, while operating the gas discharge system in output mode:
determining whether the pressure within the interior of the spectral feature adjuster body is within an operating range of pressures; and
if it is determined that the pressure within the interior of the spectral feature adjuster body is outside the operating range of pressures, then adjusting pressure of the interior of the spectral feature adjuster body.

23. The method of claim 22, wherein if it is determined that the pressure within the interior of the spectral feature adjuster body is above the operating range of pressures, then adjusting pressure of the interior of the spectral feature adjuster body comprises pumping matter out of the interior of the spectral feature adjuster body.

24. The method of claim 22, wherein if it is determined that the pressure within the interior of the spectral feature adjuster body is below the operating range of pressures, then adjusting pressure of the interior of the spectral feature adjuster body comprises opening in a controlled manner the interior of the spectral feature adjuster body to atmosphere or stopping pumping matter out of the interior of the spectral feature adjuster body.

25. The method of claim 21, further comprising, prior to operating the gas discharge system in standby mode, hermetically sealing the interior of the spectral feature adjuster body from a gas discharge cavity of the gas discharge system, the gas discharge cavity being in optical communication with the interior of the spectral feature adjuster of the gas discharge system by way of an optical pathway.

26. The method of claim 25, wherein operating the gas discharge system in output mode comprises directing a pre-cursor light beam between the gas discharge cavity and the interior of the spectral feature adjuster body so that the pre-cursor light beam interacts with optical elements within the interior of the spectral feature adjuster body.
